(19) United States
(12) Patent Application Publication
(10) Pub. No.: US 2024/0409564 A1
(43) Pub. Date: Dec. 12, 2024

(54) PEROVSKITES

(71) Applicants: Alliance for Sustainable Energy, LLC, Golden, CO (US); Board of Trustees of Northern Illinois University, DeKalb, IL (US)

(72) Inventors: Kai ZHU, Littleton, CO (US); Tao XU, Naperville, IL (US)

(21) Appl. No.: 18/712,000

(22) PCT Filed: Dec. 5, 2022
(86) PCT No.: PCT/US22/80887

§ 371 Date: May 21, 2024

Related U.S. Application Data
(60) Provisional application No. 63/285,584, filed on Dec. 3, 2021.

(51) Int. Cl. C07F 7/24

(52) U.S. Cl. CPC C07F 7/24

(57) ABSTRACT

The present disclosure relates to a composition that includes a perovskite that includes a halogen, and a capture compound, where the capture compound is capable of forming a complex with at least one of the halogen and/or an anionic form of the halogen. In some embodiments of the present disclosure, the perovskite may have a 3D crystal structure that includes a first cation, A, a second cation, B, and a halide X. In some embodiments of the present disclosure, the capture compound may be a third cation, A′, where the 3D crystal structure may have the chemical structure of of AₓA′₍₁₋ₓ₎BX₃, where 0≤x≤1.

### CROSS-REFERENCE TO RELATED APPLICATIONS

This application claims priority from U.S. Provisional Patent Application No. 63/285,584 filed on Dec. 3, 2021, the contents of which are incorporated herein by reference in their entirety.

### CONTRACTUAL ORIGIN

This invention was made with government support under Contract No. DE-AC36-08GO28308 awarded by the Department of Energy. The government has certain rights in the invention.

### BACKGROUND

Emerging perovskite solar cells-(PSCs) have high power conversion efficiency (PCE) and a potential low levelized cost of electricity of $0.02/kWh by 2030. However, the market adoption of PSCs still faces major challenges, including instability in performance over time, the toxicity issue related to the use of lead in PSCs, as well as difficulties in maintaining acceptably high PCEs when scaling up to large-area devices. Various efforts have been developed to significantly improve device operation stability. When benchmarked to silicon solar cells with a typical lifetime of over 20 years, the limited lifetime of PSCs (typically a few thousand hours) makes it difficult for practical applications. Fundamentally, the weak Pb—I-bond-energy (1.47-eV) and A+ . . . BX₃₋ cage interaction (0.3-1.4 eV) assure PSCs of superior photovoltaic (PV) performance. However, they are structurally weak when compared to the Si—Si bond-energy-(2.3-eV), which produces high stability of Si-based PV cells and modules. Thus, there remains a need for the development of new strategies that will enable the development of highly stable and efficient PSCs, which can complete with silicon PV, from both a commercialization perspective and performance perspective.

### SUMMARY

An aspect of the present disclosure is a composition that includes a perovskite that includes a halogen, and a capture compound, where the capture compound is capable of forming a complex with at least one of the halogen and/or an anionic form of the halogen. In some embodiments of the present disclosure, the perovskite may have a 3D crystal structure that includes a first cation, A, a second cation, B, and a halide, X. In some embodiments of the present disclosure, the capture compound may include a third cation, A′, where the 3D crystal structure may have the chemical structure of AₓA′₍₁₋ₓ₎BX₃, where 0≤x≤1. In some embodiments of the present disclosure, the third cation may have a molecular radius between 2.000 Å and 2.900 Å.

In some embodiments of the present disclosure, the third cation may include at least one of a thione group, a selenone group, a selenophene moiety, and/or a thiophene moiety. In some embodiments of the present disclosure, the capture compound may include at least one of protonated thiourea (TUH⁺), protonated urea, protonated thioacetamide, protonated selenourea, protonated thiophene, protonated selenophene, and/or any one of their derivatives. In some embodiments of the present disclosure, the first cation may include at least one of methyl ammonium (MA), dimethyl ammonium, ethyl ammonium, formamidinium (FA), cesium, guanidinium, benzylammonium, and/or phenethylammonium. In some embodiments of the present disclosure, the second cation may include at least one of lead and/or tin. In some embodiments of the present disclosure, the halogen may include at least one of iodide, chloride, and/or bromide.

In some embodiments of the present disclosure, the perovskite may have a chemical formula that includes Cs_{z}FA_{y}MAₓTUH⁺_{(1-x-y-z)}Pb₁₋ₘSnₘI_{3-z}Br_{z}, where each of x, y, and m are between zero and one, inclusively, and z is between zero and three, inclusively, and (1−x−y−z) is greater than zero. In some embodiments of the present disclosure, the capture compound may include at least one of a thione group, a selenone group, a selenophene moiety, or a thiophene moiety, a porous organic polymer (POP), a metal organic framework (MOF), a covalent organic framework, an ionic liquid, a metal oxide, and/or an activated carbon. In some embodiments of the present disclosure, at least a portion of the perovskite may be in the form of a plurality of grains, where each grain is surrounded by a grain boundary, and at least a portion of the capture compound is positioned within the grain boundary. In some embodiments of the present disclosure, the perovskite may be in the form of a layer. In some embodiments of the present disclosure, the capture compound may be in the form of a layer, where the capture compound layer is positioned adjacent to and in physical contact with the perovskite layer. In some embodiments of the present disclosure, the perovskite may include at least one of 3D perovskite, a 2D perovskite, a 1D perovskite, and/or a 0D perovskite.

### BRIEF DESCRIPTION OF THE DRAWINGS

Some embodiments are illustrated in referenced figures of the drawings. It is intended that the embodiments and figures disclosed herein are to be considered illustrative rather than limiting.

FIGS. 1A and 1B illustrate a perovskite in a corner-sharing, cubic phase arrangement, according to some embodiments of the present disclosure.

FIG. 2A illustrates three possible corner-sharing phases for perovskites, Panel A) cubic phase (i.e., α-ABX₃), Panel B) a tetragonal crystalline phase (i.e., β-ABX₃), and Panel C) an orthorhombic crystalline phase (i.e., γ-ABX₃), according to some embodiments of the present disclosure.

FIG. 2B illustrates a perovskite in one of the three possible phases, the cubic phase (i.e., α-phase), compared to two non-perovskite phases (i.e., non-corner sharing), according to some embodiments of the present disclosure.

FIG. 3 illustrates 2D, 1D, and 0D perovskite-like structures, in Panels A, B, and C, respectively, according to some embodiments of the present disclosure.

FIG. 4 illustrates a schematic diagram for a charge complex and possible interactions between thioureanium (TUH⁺) and iodine (I⁻), according to some embodiments of the present disclosure.

FIG. 5 illustrates nuclear magnetic resonance spectra of TUH⁺I⁻ (left: C13 NMR, right: H-NMR), an exemplary charge transfer complex, according to some embodiments of the present disclosure.

FIG. 6 illustrates XRD of TUH⁺-doped MAPbI₃, according to some embodiments of the present disclosure.

FIG. 7 illustrates results from an iodine-capture experiment, according to some embodiments of the present disclosure. These devices were made by vacuum depositing Ag directly on TUH⁺-doped and pristine MAPbI₃ (in dry air under ambient light for one month).

FIG. 8 illustrates PV performance assessment of different mol % TUH⁺ doped perovskite solar cells (PSCs), according to some embodiments of the present disclosure. These results are summarized in Table 1.

### DETAILED DESCRIPTION

The embodiments described herein should not necessarily be construed as limited to addressing any of the particular problems or deficiencies discussed herein. References in the specification to “one embodiment”, “an embodiment”, “an example embodiment”, “some embodiments”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

As used herein the term “substantially” is used to indicate that exact values are not necessarily attainable. By way of example, one of ordinary skill in the art will understand that in some chemical reactions 100% conversion of a reactant is possible, yet unlikely. Most of a reactant may be converted to a product and conversion of the reactant may asymptotically approach 100% conversion. So, although from a practical perspective 100% of the reactant is converted, from a technical perspective, a small and sometimes difficult to define amount remains. For this example of a chemical reactant, that amount may be relatively easily defined by the detection limits of the instrument used to test for it. However, in many cases, this amount may not be easily defined, hence the use of the term “substantially”. In some embodiments of the present invention, the term “substantially” is defined as approaching a specific numeric value or target to within 20%, 15%, 10%, 5%, or within 1% of the value or target. In further embodiments of the present invention, the term “substantially” is defined as approaching a specific numeric value or target to within 1%, 0.9%, 0.8%, 0.7%, 0.6%, 0.5%, 0.4%, 0.3%, 0.2%, or 0.1% of the value or target.

As used herein, the term “about” is used to indicate that exact values are not necessarily attainable. Therefore, the term “about” is used to indicate this uncertainty limit. In some embodiments of the present invention, the term “about” is used to indicate an uncertainty limit of less than or equal to ±20%, ±15%, ±10%, ±5%, or ±1% of a specific numeric value or target. In some embodiments of the present invention, the term “about” is used to indicate an uncertainty limit of less than or equal to ±1%, ±0.9%, ±0.8%, ±0.7%, ±0.6%, ±0.5%, ±0.4%, ±0.3%, ±0.2%, or ±0.1% of a specific numeric value or target.

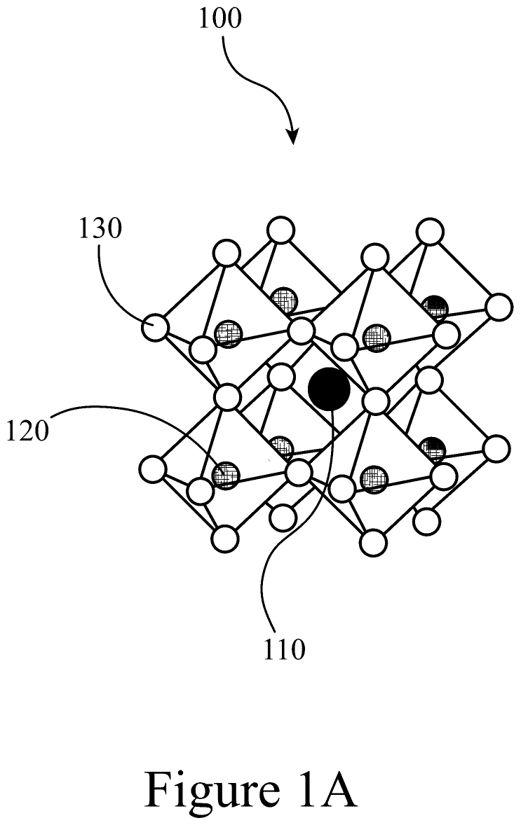

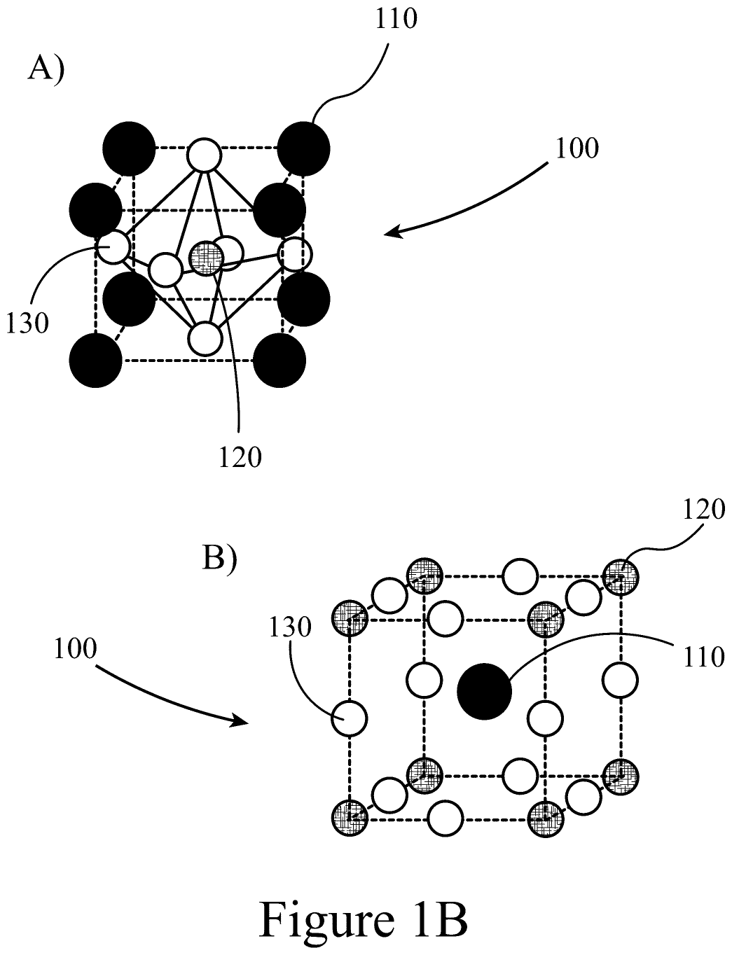

In general, the term “perovskite” refers to compositions having a network of corner-sharing BX₆ octahedra resulting in the general stoichiometry of ABX₃. FIGS. 1A and 1B illustrate that perovskites 100, for example metal halide perovskites, may organize into a three-dimensional (3D) cubic crystalline structures (i.e., α-phase or α-ABX₃) constructed of a plurality of corner-sharing BX₆ octahedra. In the general stoichiometry for a perovskite, ABX₃, X (130) is an anion and A (110) and B (120) are cations, typically of different sizes. FIG. 1A illustrates that a perovskite 100 having an α-phase structure may be further characterized by eight BX₆ octahedra surrounding a central A-cation 110, where each octahedra is formed by six X-anions 130 surrounding a central B-cation 120 and each of the octahedra are linked together by “corner-sharing” of anions, X (130).

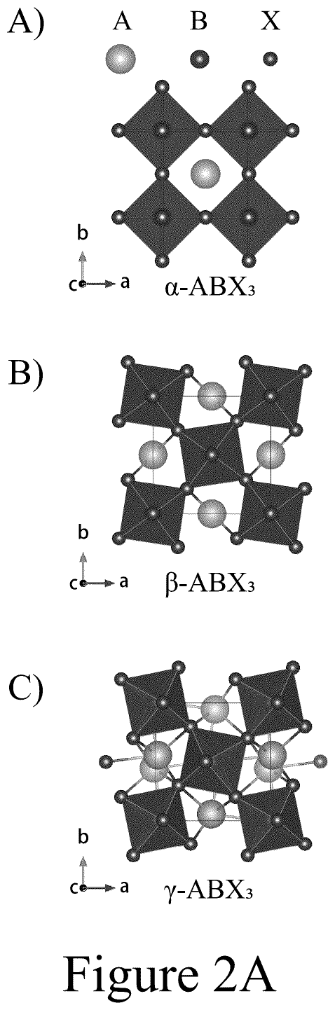

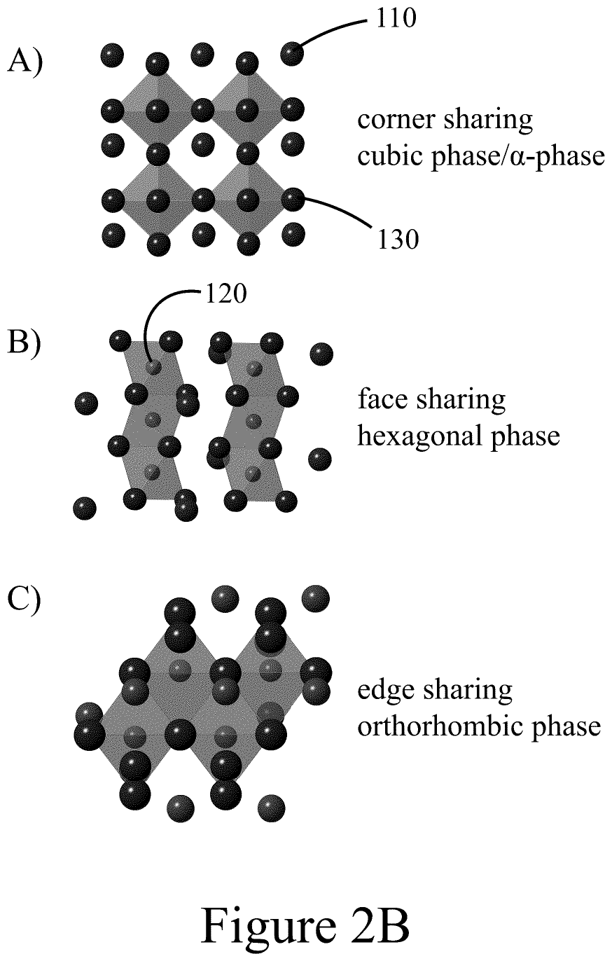

Panel A of FIG. 1B provides another visualization of a perovskite 100 in the α-phase, also referred to as the cubic phase. This is because, as shown in FIG. 1B, a perovskite in the α-phase may be visualized as a cubic unit cell, where the B-cation 120 is positioned at the center of the cube, an A-cation 110 is positioned at each corner of the cube, and an X-anion 130 is face-centered on each face of the cube. Panel B of FIG. 1B provides another visualization of the cubic unit cell of an α-phase perovskite, where the B-cation 120 resides at the eight corners of a cube, while the A-cation 110 is located at the center of the cube and with 12 X-anions 130 centrally located between B-cations 120 along each edge of the unit cell. For both unit cells illustrated in FIGS. 1B, the A-cations 110, the B-cations 120, and the X-anions 130 balance to the general formula ABX₃ of a perovskite, after accounting for the fractions of each atom shared with neighboring unit cells. For example, referring to Panel A of FIG. 1B, the single B-cation 120 atom is not shared with any of the neighboring unit cells. However, each of the six X-anions 130 is shared between two unit cells, and each of the eight A-cations 110 is shared between eight unit cells. So, for the unit cell shown in Panel A of FIG. 1B, the stoichiometry simplifies to B=1, A=8*0.125=1, and X=6*0.5=3, or ABX₃. Similarly, referring again to Panel B of FIG. 1B, since the A-cation is centrally positioned, it is not shared with any of the unit cells neighbors. However, each of the 12 X-anions 130 is shared between four neighboring unit cells, and each of the eight B-cations 120 is shared between eight neighboring unit cells, resulting in A=1, B=8*0.125=1, and X=12*0.25=3, or ABX₃. Referring again to Panel B of FIG. 1B, the X-anions 130 and the B-cations 120 of a perovskite in the α-phase are aligned along an axis; e.g., where the angle at the X-anion 130 between two neighboring B-cations 120 is exactly 180 degrees, referred to herein as the tilt angle. However, as shown in FIG. 2A, a perovskite 100 may assume other corner-sharing crystalline phases having tilt angles not equal to 180 degrees.

FIG. 2A illustrates that a perovskite can assume other crystalline forms while still maintaining the criteria of an ABX₃ stoichiometry with neighboring BX₆ octahedra maintaining X anion (130) corner-sharing. Thus, in addition to α-ABX₃ perovskites (in the cubic phase) having a tilt angle of 180 degrees, shown in Panel (a) of FIG. 2A, a perovskite may also assume a tetragonal crystalline phase (i.e., β-ABX₃) (see Panel (b) of FIG. 2A) and/or an orthorhombic crystalline phase (i.e., γ-ABX₃) (see Panel (c) of FIG. 2A), where the adjacent octahedra are tilted relative to the reference axes a, b, and c.

FIG. 2B illustrates that the elements used to construct a perovskite, as described above, A-cations 110, B-cations 120, and X-anions 130, may result in 3D non-perovskite structures; i.e., structures where neighboring BX₆ octahedra are not X-anion 130 corner-sharing and/or do not have a unit structure that simplifies to the ABX₃ stoichiometry. Referring to FIG. 2B, Panel (a) illustrates a perovskite in the cubic phase, i.e., α-ABX₃, compared to a non-perovskite structure constructed of face-sharing BX₆ octahedra resulting in a hexagonal crystalline structure (see Panel (b) of FIG. 2B) and a non-perovskite structure constructed of edge-sharing BX₆ octahedra resulting in an orthorhombic crystalline structure (see Panel (c) of FIG. 2B).

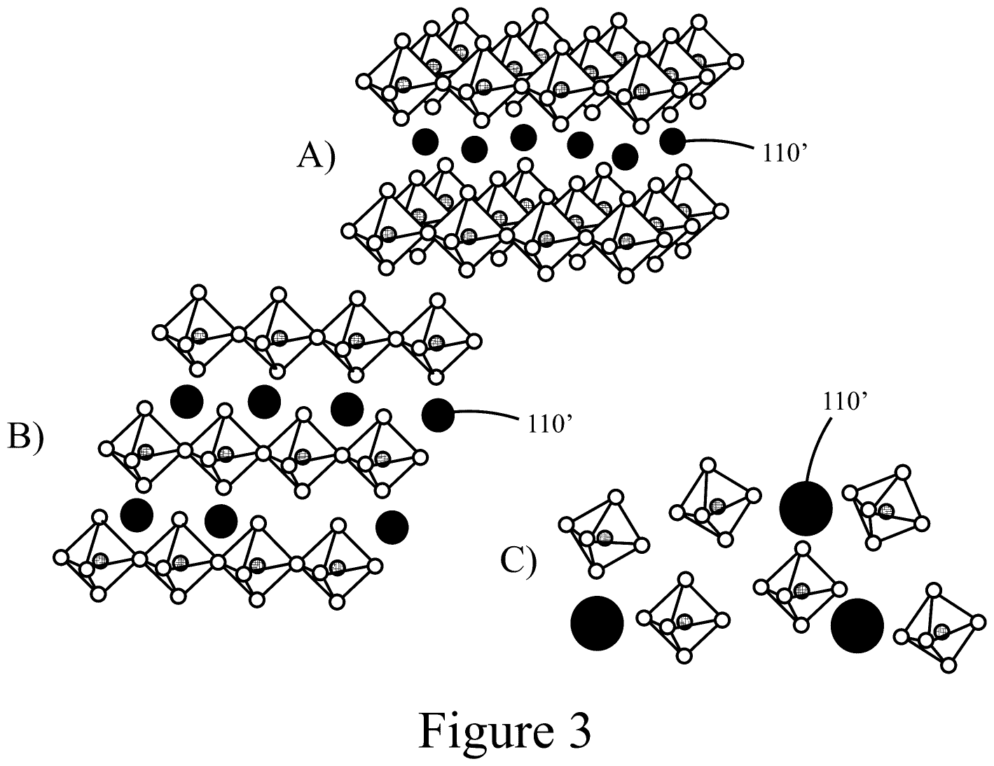

Further, referring now to FIG. 3, the elements used to construct a perovskite, as described above, A-cations 110, B-cations 120, and X-anions 130, may result in non-3D (i.e., lower dimensional structures) perovskite-like structures such as two-dimensional (2D) structures, one-dimensional (1D) structures, and/or zero-dimensional (0D) structures. As shown in FIG. 3, such lower dimensional, perovskite-like structures still include the BX₆ octahedra, and depending on the dimensionality, e.g., 2D or 1D, may still maintain a degree of X-anion corner-sharing. However, as shown in FIG. 3, the X-anion 130 corner-sharing connectivity of neighboring octahedra of such lower dimensional structures, i.e., 2D, 1D, and 0D, is disrupted by intervening A-cations 110. Such a disruption of the neighboring octahedra, can be achieved by, among other things, varying the size of the intervening A-cations 110.

Referring to Panel A of FIG. 3, a 3D perovskite may be transformed to a 2D perovskite-like structure, 1D perovskite-like structure, and/or 0D perovskite-like structure. Where the degree of X-anion 130 corner sharing decreases and the stoichiometry changes according to the formula (A′)ₘ(A)ₙ₋₁BₙX₃ₙ₊₁, where monovalent (m=2) or divalent (m=1) A′ cations 110′ can intercalate between the X-anions of 2D perovskite-like sheets. Referring to Panel B of FIG. 3, 1D perovskite-like structures are constructed by BX₆ octahedral chained segments spatially isolated from each other by surrounding bulky organic A′-cations 110′, leading to bulk assemblies of paralleled octahedral chains. Referring to Panel C of FIG. 3, typically, the 0D perovskite-like structures are constructed of isolated inorganic octahedral clusters and surrounded by small A′-cations 110′, which may be connected via hydrogen bonding. In general, as n approaches infinity the structure is a pure 3D perovskite and when n is equal to 1, the structure is a pure 2D perovskite-like structure. More specifically, when n is greater than 10 the structure is considered to be essentially a 3D perovskite material and when n is between 1 and 5, inclusively, the structure is considered substantially a 2D perovskite-like material.

In some embodiments of the present invention, the A-cation 110 may include a nitrogen-containing organic compound such as an alkyl ammonium compound. The B-cation 120 may include a metal and the X-anion 130 may include a halogen. Additional examples for the A-cation 110 include organic cations and/or inorganic cations, for example Cs, Rb, K, Na, Li, and/or Fr. Organic A-cations 110 may be an alkyl ammonium cation, for example a C₁₋₂₀ alkyl ammonium cation, a C₁₋₆ alkyl ammonium cation, a C₂₋₆ alkyl ammonium cation, a C₁₋₅ alkyl ammonium cation, a C₁₋₄ alkyl ammonium cation, a C₁₋₃ alkyl ammonium cation, a C₁₋₂ alkyl ammonium cation, and/or a C₁ alkyl ammonium cation. Further examples of organic A-cations 110 include methylammonium (CH₃NH₃⁺), ethylammonium (CH₃CH₂NH₃⁺), propylammonium (CH₃CH₂ CH₂NH₃⁺), butylammonium (CH₃CH₂ CH₂ CH₂NH₃⁺), formamidinium (NH₂CH═NH₂⁺), hydrazinium, acetylammonium, dimethylammonium, imidazolium, guanidinium, benzylammonium, phenethylammonium, butylammonium and/or any other suitable nitrogen-containing or organic compound. In other examples, an A-cation 110 may include an alkylamine. Thus, an A-cation 110 may include an organic component with one or more amine groups. For example, an A-cation 110 may be an alkyl diamine halide such as formamidinium (CH(NH₂)₂). Thus, the A-cation 110 may include an organic constituent in combination with a nitrogen constituent. In some cases, the organic constituent may be an alkyl group such as straight-chain or branched saturated hydrocarbon group having from 1 to 20 carbon atoms. In some embodiments, an alkyl group may have from 1 to 6 carbon atoms. Examples of alkyl groups include methyl (C₁), ethyl (C₂), n-propyl (C₃), isopropyl (C₃), n-butyl (C₄), tert-butyl (C₄), sec-butyl (C₄), iso-butyl (C₄), n-pentyl (C₅), 3-pentanyl (C₅), amyl (C₅), neopentyl (C₅), 3-methyl-2-butanyl (C₅), tertiary amyl (C₅), and n-hexyl (C₆). Additional examples of alkyl groups include n-heptyl (C₇), n-octyl (C₈) and the like. Examples of metal B-cations 120 include, for example, lead, tin, germanium, and or any other 2+ valence state metal that can charge-balance the perovskite 100. Further examples include transition metals in the 2+ state such as Mn, Mg, Zn, Cd, and/or lanthanides such as Eu. B-cations may also include elements in the 3+ valence state, as described below, including for example, Bi, La, and/or Y. Examples for X-anions 130 include halogens: e.g., fluorine, chlorine, bromine, iodine and/or astatine. In some cases, the perovskite halide may include more than one X-anion 130, for example pairs of halogens; chlorine and iodine, bromine and iodine, and/or any other suitable pairing of halogens. In other cases, the perovskite 100 may include two or more halogens of fluorine, chlorine, bromine, iodine, and/or astatine.

Thus, the A-cation 110, the B-cation 120, and X-anion 130 may be selected within the general formula of ABX₃ to produce a wide variety of perovskites 100, including, for example, methylammonium lead triiodide (CH₃NH₃PbI₃), and mixed halide perovskites such as CH₃NH₃PbI₃₋ₓClₓ and CH₃NH₃PbI₃₋ₓBrₓ. Thus, a perovskite 100 may have more than one halogen element, where the various halogen elements are present in non-integer quantities; e.g., x is not equal to 1, 2, or 3. In addition, perovskite halides, like other organic-inorganic perovskites, can form three-dimensional (3-D), two-dimensional (2-D), one-dimensional (1-D) or zero-dimensional (0-D) networks, possessing the same unit structure. As described herein, the A-cation 110 of a perovskite 100, may include one or more A-cations, for example, one or more of cesium, FA, MA, etc. Similarly, the B-cation 120 of a perovskite 100, may include one or more B-cations, for example, one or more of lead, tin, germanium, etc. Similarly, the X-anion 130 of a perovskite 100 may include one or more anions, for example, one or more halogens (e.g., at least one of I, Br, Cl, and/or F), thiocyanate, and/or sulfur. Any combination is possible provided that the charges balance.

For example, a perovskite having the basic crystal structure illustrated in FIGS. 1A and 1B, in at least one of a cubic, orthorhombic, and/or tetragonal structure, may have other compositions resulting from the combination of the cations having various valence states in addition to the 2+ state and/or 1+ state described above for lead and alkyl ammonium cations; e.g., compositions other than AB²⁺X₃ (where A is one or more cations, or for a mixed perovskite where A is two or more cations). Thus, the methods described herein may be utilized to create novel mixed cation materials having the composition of a double perovskite (elpasolites), A₂B¹⁺B³⁺X₆, with an example of such a composition being Cs₂BiAgCl₆ and Cs₂CuBiI₆. Another example of a composition covered within the scope of the present disclosure is described by A₂B⁴⁺X₆, for example Cs₂PbI₆ and Cs₂SnI₆. Yet another example is described by A₃B₂³⁺X₉, for example Cs₃Sb₂I₉. For each of these examples, A is one or more cations, or for a mixed perovskite, A is two or more cations.

Among other things, the present disclosure relates to innovative methods and compositions that increase the stability of perovskites, as determined by, among other things, visual appearance of the perovskites and the length time, i.e., lifespan, of suitable operating performance. One key factor relating to the instability of perovskites is the migration of halides (i.e., X⁻ anions; e.g., I⁻, and/or Br⁻) in the perovskite lattice as well as the photo-reaction of halides to atomic or molecular halogen (I, I₂, Br, or Br₂, etc.) and/or polyatomic halide anions ([I₃]⁻, [I₅]⁻, [I₇]⁻, [Br₃]⁻, etc.), and their subsequent migration through the perovskite, grain boundaries, and/or any of the interfaces present in the device stack containing the perovskite. Migration by any one or more of these species (e.g., X, X₂, X⁻, (Xₙ)⁻¹, where n is any odd integer value) through the perovskite crystal structure and/or elsewhere within a perovskite-containing photovoltaic device is referred to herein as “halogen migration”.

As described herein, halogen migration may be suppressed via a charge transfer complex interaction. Here, a charge transfer complex, also known as electron donor-acceptor complex, is defined as an association of two or more molecules or species, or of different parts of one large molecule or species, in which a fraction of electronic charge is transferred between the molecular entities and/or species. In some embodiments of the present disclosure, the resulting electrostatic attraction provides a stabilizing force for the resulting molecular complex, namely the charge transfer complex. The source molecule/species from which the electron is transferred is called the electron donor, and the species that receives the electron is called the electron acceptor. This process/method of using charge transfer interactions to suppress the migration of halogen species in perovskite materials is generally referred to in this disclosure as “halogen management”. Halogen management may be achieved using at least two approaches, where the first approach is referred to herein as an “incorporation method” and the second approach is referred to as an “absorption method”. In some embodiments of the present disclosure, both methods may be using simultaneously in the same device.

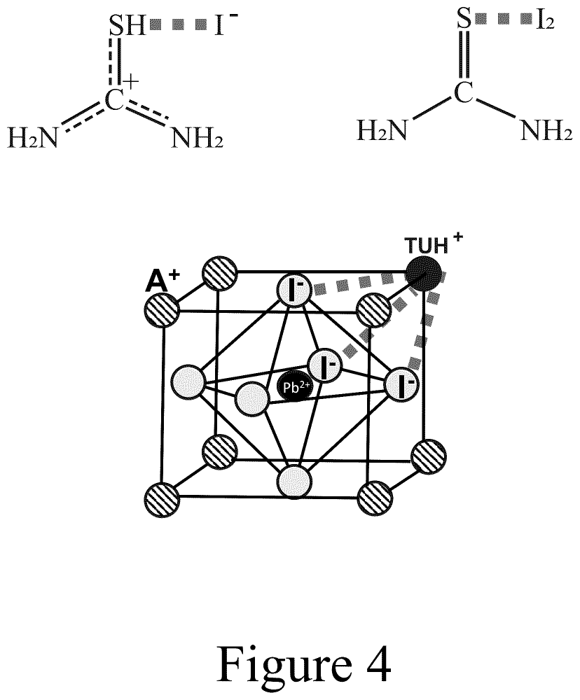

When utilizing the “incorporation method”, at least a portion of the A-cations commonly used to synthesize perovskite crystals, e.g., methyl ammonium, formamidinium, and/or cesium, is replaced with other cations, “capture compounds”, that can form strong charge transfer complexes with the degradation products formed by the halides, X-anions, present in the perovskite crystal structure. This concept is illustrated in FIG. 4, which shows protonated thiourea (TUH⁺) as an exemplary capture compound replacing one of the A-site cations. These “other” A-cations are referred to herein as “degradation product capture compounds” or “capture compound” for short. In the charge transfer complex pair described above, a capture compound utilized in the incorporation method is the electron acceptor and the halide, X-anion, is the electron donor. Thus, referring again to FIG. 4, when using the incorporation method, at least a portion of a capture compound is positioned in the perovskite lattice, which is in the exemplary case TUH⁺. FIG. 4 also illustrates two examples of possible electrostatic interactions between the TUH⁺ capture compound and both an ionic form of the halogen used in the perovskite, I—, and a molecular form of the halogen, I₂. This positioning in the perovskite lattice provides a halogen capture mechanism of the degradation products resulting from the degradation of the halides normally positioned within the perovskite lattice, with some degradation products including atomic halogens and/or molecular halogens and/or polyatomic halide anions, as described above. As shown herein, the halogen incorporation method prevents, or at least greatly minimizes, the migration of the halogen degradation products out of the perovskite crystal structure, and thereby reduces or eliminates perovskite degradation and extends the lifespan of the solar cell and/or solar module constructed with the perovskite as the active material.

Other examples of capture compounds, in addition to protonated thiourea (TUH⁺), include a variety of molecules that include, for example, protonated urea, protonated thioacetamide, protonated selenourea, protonated thiophene, protonated selenophene, and/or their derivatives. In general, a capture compound for use in the incorporation method should be small enough in size to fit into the perovskite lattice while maintaining its three-dimensional (3-D) perovskite structure. The approximate molecular radius of (TUH⁺) is about 2.777 Å. For comparison, the radii of other cations which may be used as the A-site cation in perovskite formulations are as follows: Cs⁺ 1.67 Å; formamidinium (FA⁺) 2.53 Å; and methylammonium (MA⁺) 2.16 Å. Therefore, protonated capture compounds having a molecular radius between 2.000 Å and 3.000 Å, or between 2.600 Å and 3.000 Å, may successfully prevent halogen migration via halogen management using the incorporation method.

Referring again to FIG. 4, without wishing to be bound by theory, it is possible that the capture compound incorporation method is achieved due to an interaction between the protonated capture compound and the halogen degradation product. For example, protonated thiourea (TUH⁺), an exemplary carbon capture compound, and I—, a halogen degradation product, may interact in the perovskite lattice structure via a pseudohydrogen bond (H—N—)(H—N═)C—S—H . . . I—, which may enhance the overall stability of the perovskite structure. For the example of iodide and TUH⁺, the high equilibrium constant (>14,000) for the formation of a TU-I₂ charge transfer complex, indicates that the formation of the charge transfer complex is likely to occur and may effectively suppress the migration of iodine inside the perovskite lattice and/or grain boundaries.

The second approach, the absorption method, may utilize a thin layer of a degradation product capture compound deposited onto a “standard” perovskite layer (e.g., MA_{(1-x-y)}FAₓCs_{y}PbI_{(3-z)}Br_{z}). The capture compound layer can then form strong charge transfer complexes with halogen degradation products; e.g. atomic or molecular halogen (I, I₂, Br, Br₂, etc.) and/or polyatomic halides anions ([I₃]⁻, [I₅]⁻, [I₇]⁻, [Br₃]⁻, etc.). For this approach, the capture compound is not placed in the lattice (or not solely placed in the lattice) of the perovskite crystal, but instead, is positioned in a separate thin layer that is adjacent to the perovskite. Alternatively, or in addition to forming a layer of a capture compound on a perovskite absorber layer, a capture compound may be concentrated in the grain boundaries of the perovskite layers. The nature of grain boundaries and other defective sites in the perovskite film are where broken Pb—X bonds, (X=Cl, Br, I) are enriched. The strong interaction between the capture compound and the halogen may form charge transfer complexes like those described above, resulting in the local depletion concentration of the capture compound in the solution phase, thereby allowing a self-propelled diffusion mechanism of the capture compound towards the grain boundaries and other defects within the perovskite.

Unlike the incorporation method, which places a maximum allowable limit on the size of the capture compound, e.g., between 2.000 Å and 3.000 Å, the absorption method has no such limitation. For example, the unprotonated forms of TUH⁺, i.e., thiourea, and urea, thioacetamide, selenourea, thiophene, selenophene, and/or their derivatives may be utilized in the absorption method. However, in some embodiments of the present disclosure, the protonated versions of capture compounds may be utilized in the absorption method, alone or in addition to the unprotonated forms of the capture compounds. So, a number of classes of chemical compounds may be used as capture compounds for either of the two methods described above, the incorporation method and/or the absorption method.

In addition to C═S containing degradation product capture compounds, like thiophene, other exemplary classes of compounds and molecules that may provide the same advantages by acting as capture compounds, are listed below. Depending on the size (see above), these capture compounds may be protonated and/or unprotonated (i.e., charge balanced).
1) In place of and/or in addition to the C═S compounds described above, selenium-based organic molecules containing at least one Se—C bond may be used as degradation product capture compounds. An example includes selenophene and its derivatives such as poly(3,4-ethylenedioxyselenophene).
2) Porous organic polymers (POP) including naturally occurring species (e.g., amylose) and synthetic species such as hexaphenylbenzene-based conjugated microporous polymers, metalloporphyrin-based NiP-conjugated microporous polymers, thiophene-based conjugated microporous polymers, selenophene-based conjugated microporous polymers, and BODIPY-based conjugated microporous polymers. The concepts described herein include the use of POP-based halogen capture compounds in perovskite materials that contains halogens.
3) Metal organic framework (MOF): MOFs represent a large variety of compounds that can capture halogens. The concepts described herein include the use of MOF-based halogen capture compounds. Examples of MOFs that can absorb iodine are MOF Cu-BTC (also known as HKUST-1), [(ZnI2)3(tpt)2], and/or ZIF-8.
4) Other materials such as ionic liquids (such as 1-ethyl-3-methylimidazolium (EMIM⁺) boron tetrafluoride (BF₄⁻), and 1-butyl-3-methylimidazolium hexafluorophosphate (BMIM+) BF₄⁻), covalent organic frameworks (COF, such as SIOC-COF-7, COF-DL229, hydrogen-bonded COF (H_{C}OF-1)), metal oxides (such as silver-containing zeolites, Ag₂O on Mg(OH)₂ and/or activated carbon (such as triethylenediamine impregnated porous carbon, and activated carbons impregnated with KI).

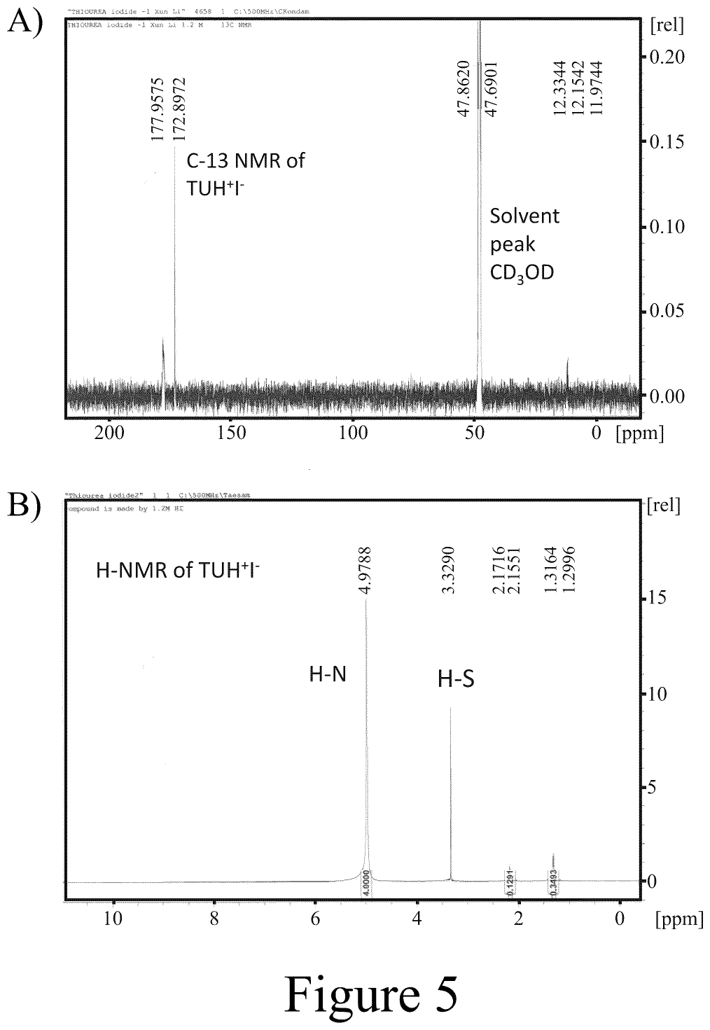

Experimental: Synthesis of TUH⁺I⁻ was successfully prepared using careful pH control, as evidenced by its C-13 nuclear magnetic resonance (NMR) spectrum (see FIG. 5) that is in excellent agreement with reported value. TUHI was synthesized by dissolving Tu in 1.25 M HI solution with a molar ration of TU:HI=1:1.2. This solution was kept in ice bath (0 degree) under stirring for 2 hrs. Then it was dried off by heating on hotplate at 65° C. The solid was collected and washed by ether for serval times until the color changes to white. Finally, the white powder was kept in vacuum oven at 55° C. overnight before being collected for further use.

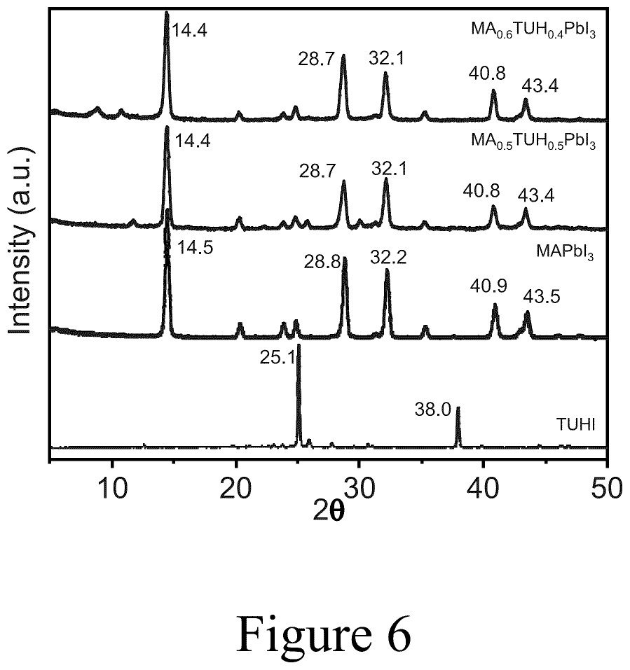

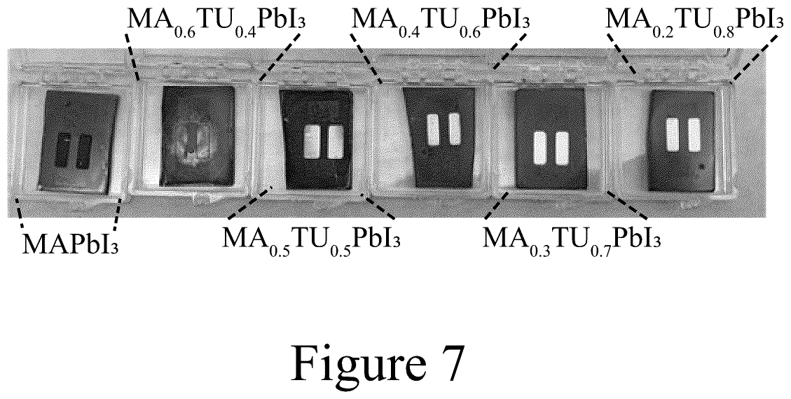

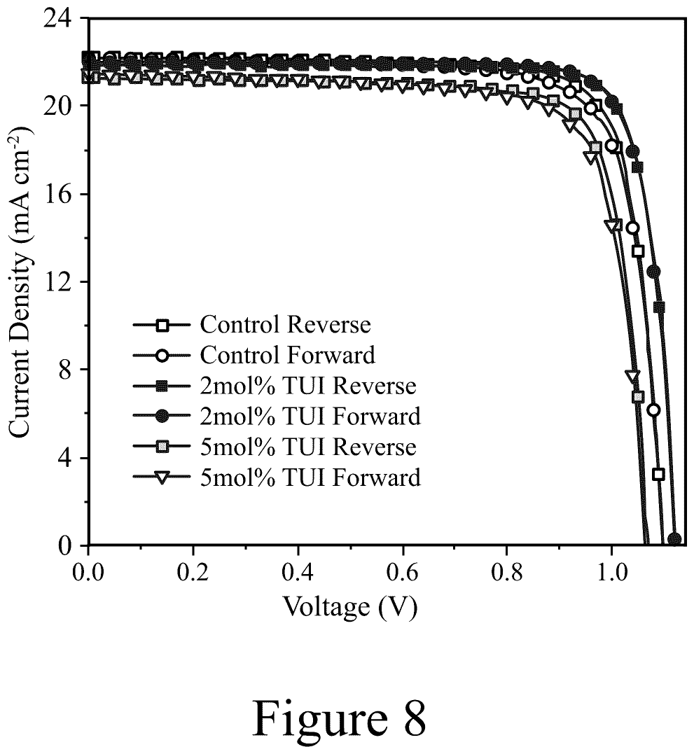

This study shows TUH⁺-doped MAPbI₃ exhibits similar XRD (see FIG. 6) as MAPbI₃, implying two possible locations of TUH⁺, either in A⁺ site or in grain boundaries as in amorphous phase. Surprisingly, the resulting films showed marked inertness to silver (less tarnishing than on pure MAPbI₃) after Ag film was directly deposited on TUH⁺-doped MAPbI₃ (no HTL in between) for accelerated degradation testing (see FIG. 7). The same improvements are expected for other perovskite compositions. In addition, TUH⁺ doped PSCs were manufactured and their PV performance tested, with the resultant performance metrics summarized in FIG. 8. The results show that a 2 mol % doping of TUH⁺ provided a PCE of 20.35% with markedly improved FF (0.832) compared to the undoped control (PCE=19.54%, FF=0.799). The improved FF is an indication of reduced recombination, possibly due to the presence of TUH⁺ at grain boundaries or decreased structural defects by the CT interaction between TUH⁺ and I⁻ even during the film preparation process. Increased amounts of the TUH⁺ deteriorated the film absorption, resulting in a loss of J_{sc}. So, there appears to be an optimum amount capture compound to be incorporated into a given perovskite formulation, which is not necessarily apparent without completing experimental studies.

### EXAMPLES

Example 1. A composition comprising: a perovskite comprising a halogen, and a capture compound, wherein: the capture compound is capable of forming a complex with at least one of the halogen or an anionic form of the halogen.

Example 2. The composition of Example 1, wherein: the perovskite has a 3D crystal structure comprising: a first cation, A, a second cation, B, and a halide X.

Example 3. The composition of either Example 1 or Example 2, wherein: the capture compound comprises a third cation, A′, and the 3D crystal structure comprises AₓA′₍₁₋ₓ₎BX₃, where 0≤x≤1.

Example 4. The composition of any one of Examples 1-3, wherein the third cation has a molecular radius between 2.000 Å and 2.900 Å.

Example 5. The composition of any one of Examples 1-4, wherein the molecular radius is between 2.600 Å and 2.900 Å.

Example 6. The composition of any one of Examples 1-5, wherein the third cation comprises at least one of a thione group, a selenone group, a selenophene moiety, or a thiophene moiety.

Example 7. The composition of any one of Examples 1-6, wherein the capture compound comprises at least one of protonated thiourea (TUH⁺), protonated urea, protonated thioacetamide, protonated selenourea, protonated thiophene, protonated selenophene, or any one or more of their derivatives.

Example 8. The composition of any one of Examples 1-7, wherein the first cation comprises at least one of methyl ammonium (MA), dimethyl ammonium, ethyl ammonium, formamidinium (FA), cesium, guanidinium, benzylammonium, or phenethylammonium.

Example 9. The composition of any one of Examples 1-8, wherein the second cation comprises at least one of lead or tin.

Example 10. The composition of any one of Examples 1-9, wherein the halogen comprises at least one of iodide, chloride, or bromide.

Example 11. The composition of any one of Examples 1-10, wherein: the perovskite comprises Cs_{z}FA_{y}MAₓTUH⁺_{(1-x-y-z)}Pb₁₋ₘSnₘI_{3-z}Br_{z}, each of x, y, and m are between zero and one, inclusively, z is between zero and three, inclusively, and (1−x−y−z) is greater than zero.

Example 12. The composition of any one of Examples 1-11, wherein the perovskite comprises MAₓTUH⁺₁₋ₓPbX₃, and 0<x≤0.5.

Example 13. The composition of any one of Examples 1-12, wherein the capture compound comprises at least one of a thione group, a selenone group, a selenophene moiety, a thiophene moiety, a porous organic polymer (POP), a metal organic framework (MOF), a covalent organic framework, an ionic liquid, a metal oxide, or an activated carbon.

Example 14. The composition of any one of Examples 1-13, wherein the capture compound comprises at least one of urea, thiourea, thioacetamide, thiophene, polythiophene, 1-cyclohexyl-3-(iso-butyl)thiourea, 1-cyclohexyl-3-(tert-butyl)thiourea, 1-cyclohexyl-3-(3-chlorophenyl)thiourea, or any of their derivatives.

Example 15. The composition of any one of Examples 1-14, wherein the capture compound comprises at least one of selenourea, protonated selenourea, or 1,1-dimethyl-2-selenourea.

Example 16. The composition of any one of Examples 1-15, wherein the capture compound comprises at least one of 2,2′-bithiophene or thieno[3,2-b]thiophene.

Example 17. The composition of any one of Examples 1-16, wherein the capture compound comprises at least one of poly(3,4-ethylenedioxyselenophene), benzoselenophene, or 2-methyl selenophene.

Example 18. The composition of any one of Examples 1-17, wherein the POP comprises at least one of amylose, a hexaphenylbenzene-containing polymer, a metalloporphoryin-based polymer (NiP-CMP), 4,4-Difluoro-4-bora-3a,4a-diaza-s-indacene) (BODIPY), or a BODIPY-based polymer.

Example 19. The composition of any one of Examples 1-18, wherein the hexaphenylbenzene-containing polymer comprises at least one of HCMP-1,2,3,4, or POP-1,2.

Example 20. The composition of any one of Examples 1-19, wherein the MOF comprises at least one of Cu-BTC, [(ZnI2)3(tpt)2], or ZIF-8.

Example 21. The composition of any one of Examples 1-20, wherein the ionic liquid comprises at least one of 1-ethyl-3-methylimidazolium boron tetrafluoride, or 1-butyl-3-methylimidazolium hexafluorophosphate.

Example 22. The composition of any one of Examples 1-21, wherein the COF comprises at least one SIOC-COF-7, COF-DL229, or H_{C}OF-1.

Example 23. The composition of any one of Examples 1-22, wherein the metal oxide comprises at least one of a zeolite, Ag₂O, or Mg(OH)₂.

Example 24. The composition of any one of Examples 1-23, wherein the activated carbon further comprises at least one of triethylenediamine or KI.

Example 25. The composition of any one of Examples 1-24, wherein the capture compound is protonated.

Example 26. The composition of any one of Examples 1-25, wherein: at least a portion of the perovskite is in the form of a plurality of grains, each grain is surrounded by a grain boundary, and at least a portion of the capture compound is positioned within the grain boundary.

Example 27. The composition of any one of Examples 1-26, wherein the capture compound is at a concentration between about 0.1 mol % and about 80 mol % relative to the first cation.

Example 28. The composition of any one of Examples 1-27, wherein the concentration is between about 0.1 mol % and about 10 mol % relative to the first cation.

Example 29. The composition of any one of Examples 1-28, wherein the perovskite is in the form of a layer.

Example 30. The composition of any one of Examples 1-29, wherein the perovskite layer has a thickness layer between 50 nm and 700 nm.

Example 31. The composition of any one of Examples 1-30, wherein the thickness is between 500 nm and 600 nm.

Example 32. The composition of any one of Examples 1-31, wherein: the capture compound is in the form of a layer, and the capture compound layer is positioned adjacent to and in physical contact with the perovskite layer.

Example 33. The composition of any one of Examples 1-32, wherein the capture compound layer has a thickness between 100 nm and 1000 nm.

Example 34. The composition of any one of Examples 1-33, wherein the thickness is between 400 nm and 600 nm.

Example 35. The composition of any one of Examples 1-34, wherein the capture compound is at a concentration between about 0.1 mol % and about 80 mol % relative to the first cation.

Example 36. The composition of any one of Examples 1-35, wherein the concentration is between about 0.1 mol % and about 10 mol % relative to the first cation.

Example 37. The composition of any one of Examples 1-36, wherein the perovskite comprises at least one of 3D perovskite, a 2D perovskite, a 1D perovskite, or a 0D perovskite.

The foregoing discussion and examples have been presented for purposes of illustration and description. The foregoing is not intended to limit the aspects, embodiments, or configurations to the form or forms disclosed herein. In the foregoing Detailed Description for example, various features of the aspects, embodiments, or configurations are grouped together in one or more embodiments, configurations, or aspects for the purpose of streamlining the disclosure. The features of the aspects, embodiments, or configurations, may be combined in alternate aspects, embodiments, or configurations other than those discussed above. This method of disclosure is not to be interpreted as reflecting an intention that the aspects, embodiments, or configurations require more features than are expressly recited in each claim. Rather, as the following claims reflect, inventive aspects lie in less than all features of a single foregoing disclosed embodiment, configuration, or aspect. While certain aspects of conventional technology have been discussed to facilitate disclosure of some embodiments of the present invention, the Applicants in no way disclaim these technical aspects, and it is contemplated that the claimed invention may encompass one or more of the conventional technical aspects discussed herein. Thus, the following claims are hereby incorporated into this Detailed Description, with each claim standing on its own as a separate aspect, embodiment, or configuration.

What is claimed is:

1. A composition comprising:
a perovskite comprising a halogen, and
a capture compound, wherein:
the capture compound is capable of forming a complex with at least one of the halogen or an anionic form of the halogen.

2. The composition of claim 1, wherein:
the perovskite has a 3D crystal structure comprising:
a first cation, A,
a second cation, B, and
a halide X.

3. The composition of claim 2, wherein:
the capture compound comprises a third cation, A′, and
the 3D crystal structure comprises AₓA′₍₁₋ₓ₎BX₃, where 0≤x≤1.

4. The composition of claim 3, wherein the third cation has a molecular radius between 2.000 Å and 2.900 Å.

5. The composition of claim 3, wherein the third cation comprises at least one of a thione group, a selenone group, a selenophene moiety, or a thiophene moiety.

6. The composition of claim 5, wherein the capture compound comprises at least one of protonated thiourea (TUH⁺), protonated urea, protonated thioacetamide, protonated selenourea, protonated thiophene, protonated selenophene, or any one or more of their derivatives.

7. The composition of claim 2, wherein the first cation comprises at least one of methyl ammonium (MA), dimethyl ammonium, ethyl ammonium, formamidinium (FA), cesium, guanidinium, benzylammonium, or phenethylammonium.

8. The composition of claim 2, wherein the second cation comprises at least one of lead or tin.

9. The composition of claim 2, wherein the halogen comprises at least one of iodide, chloride, or bromide.

10. The composition of claim 3, wherein:
the perovskite comprises Cs_{z}FA_{y}MAₓTUH⁺_{(1-x-y-z)}Pb₁₋ₘSnₘI_{3-z}Br_{z},
each of x, y, and m are between zero and one, inclusively, and z is between zero and three, inclusively, and (1−x−y−z) is greater than zero.

11. The composition of claim 1, wherein the capture compound comprises at least one of a thione group, a selenone group, a selenophene moiety, or a thiophene moiety, a porous organic polymer (POP), a metal organic framework (MOF), a covalent organic framework, an ionic liquid, a metal oxide, or an activated carbon.

12. The composition of claim 1, wherein:
at least a portion of the perovskite is in the form of a plurality of grains,
each grain is surrounded by a grain boundary, and
at least a portion of the capture compound is positioned within the grain boundary.

13. The composition of claim 1, wherein the perovskite is in the form of a layer.

14. The composition of claim 13, wherein:
the capture compound is in the form of the layer, and
the capture compound layer is positioned adjacent to and in physical contact with the perovskite layer.

15. The composition of claim 1, wherein the perovskite comprises at least one of 3D perovskite, a 2D perovskite, a 1D perovskite, or a 0D perovskite.
